(19) United States
(12) Patent Application Publication
(10) Pub. No.: US 2024/0201600 A1
(43) Pub. Date: Jun. 20, 2024

(54) IMPRINT METHOD, METHOD OF MANUFACTURING SEMICONDUCTOR DEVICE, AND METHOD OF MANUFACTURING TEMPLATE

(71) Applicant: Kioxia Corporation, Tokyo (JP)

(72) Inventor: Kasumi OKABE, Nagoya Aichi (JP)

(73) Assignee: Kioxia Corporation, Tokyo (JP)

(21) Appl. No.: 18/447,679

(22) Filed: Aug. 10, 2023

(30) Foreign Application Priority Data
Dec. 16, 2022 (JP) 2022-201228

(51) Int. Cl. G03F 7/00; G03F 1/38; G03F 1/80; G03F 7/075; G03F 7/16

(52) U.S. Cl. CPC G03F 7/70341; G03F 1/38; G03F 1/80; G03F 7/075; G03F 7/161

(57) ABSTRACT

A method of manufacturing a semiconductor device, a processing target layer is formed on a substrate, a stopper film is formed on an upper surface of the processing target layer, a transfer target material is applied to the upper surface of the processing target layer on which the stopper film is formed, and a pattern of a template is transferred to the transfer target material by bringing the template into contact with the transfer target material and the transfer target material is cured. The template is released from the cured transfer target material, a reversal agent layer is formed on the cured transfer target material, and the processing target layer and the substrate are processed using the reversal agent layer as a mask.

### CROSS-REFERENCE TO RELATED APPLICATION (S)

This application is based upon and claims the benefit of priority from Japanese Patent Application No. 2022-201228, filed Dec. 16, 2022, the entire contents of which are incorporated herein by reference.

### FIELD

Embodiments described herein relate generally to an imprint method, a method of manufacturing a semiconductor device, and a method of manufacturing a template.

### BACKGROUND

As methods of forming minute patterns, imprint methods have been proposed. In imprint methods, resists are applied to processing target films, templates in which the minute patterns are formed are pressed against the resists, recess portions of the templates are filled with the resists, and then the resists are irradiated with ultraviolet light to be cured. The resists released from the templates serve as masks when the processing target films are processed.

### DESCRIPTION OF THE DRAWINGS

FIG. 1 is a perspective view illustrating a perspective structure of a semiconductor device according to a first embodiment;

FIG. 2 is a perspective view illustrating a perspective structure of a memory cell region and a contact region of the semiconductor device according to the first embodiment;

FIG. 3 is a sectional view illustrating a cross-sectional structure of a stacked wiring structure according to the first embodiment;

FIG. 4 is a sectional view illustrating some of steps of manufacturing the stacked wiring structure according to the first embodiment;

FIG. 5 is a sectional view illustrating some of the steps of manufacturing the stacked wiring structure according to the first embodiment;

FIG. 6 is a sectional view illustrating some of the steps of manufacturing the stacked wiring structure according to the first embodiment;

FIG. 7 is a sectional view illustrating some of the steps of manufacturing the stacked wiring structure according to the first embodiment;

FIG. 8 is a sectional view illustrating some of the steps of manufacturing the stacked wiring structure according to the first embodiment;

FIG. 9 is a sectional view illustrating some of the steps of manufacturing the stacked wiring structure according to the first embodiment;

FIG. 10 is a diagram schematically illustrating a schematic configuration of an imprint device according to the first embodiment;

FIGS. 11A to 11C are sectional views illustrating some of steps of manufacturing a substrate according to the first embodiment;

FIGS. 12A to 12C are sectional views illustrating some of the steps of manufacturing the substrate according to the first embodiment;

FIGS. 13A and 13B are sectional views illustrating some of the steps of manufacturing the substrate according to the first embodiment;

FIGS. 14A to 14C are sectional views illustrating some of the steps of manufacturing the substrate according to the first embodiment;

FIGS. 15A and 15B are sectional views illustrating some of the steps of manufacturing the substrate according to the first embodiment;

FIGS. 16A and 16B are sectional views illustrating some of steps of manufacturing a substrate according to a reference example;

FIGS. 17A to 17C are sectional views illustrating some of steps of manufacturing a substrate according to a second embodiment;

FIGS. 18A to 18C are sectional views illustrating some of the steps of manufacturing a substrate according to the second embodiment;

FIGS. 19A and 19B are sectional views illustrating some of the steps of manufacturing a substrate according to the second embodiment;

FIGS. 20A to 20D are sectional views illustrating some of steps of manufacturing a substrate according to a third embodiment;

FIGS. 21A to 21C are sectional views illustrating some of the steps of manufacturing the substrate according to the third embodiment; and

FIG. 22 is a sectional view illustrating some of steps of manufacturing a substrate according to another embodiment.

### DETAILED DESCRIPTION

Embodiments provide an imprint method, a method of manufacturing a semiconductor device, and a method of manufacturing a template capable of improving processing accuracy.

In general, according to at least one embodiment, an imprint method is an imprint method of applying a transfer target material to a shot region on a processing target layer formed on a processing target object and transferring a pattern of a template to the transfer target material. The imprint method includes: forming the processing target layer on the processing target object; forming a stopper film that has higher processing resistance than the processing target layer in a region corresponding to an outer circumference of the shot region on an upper surface of the processing target layer; applying the transfer target material to the shot region on the upper surface of the processing target layer on which the stopper film is formed; transferring the pattern of the template to the transfer target material by bringing the template into contact with the transfer target material, and curing the transfer target material; releasing the template from the cured transfer target material; forming a reversal agent layer on the cured transfer target material so that a part of the cured transfer target material is exposed; and processing the processing target layer and the processing target object using the reversal agent layer as a mask.

An imprint method according to another embodiment is an imprint method of applying a transfer target material to a shot region on a processing target layer formed on a processing target object and transferring a pattern of a template to the transfer target material. The imprint method includes: forming a stopper film that has higher processing resistance than the processing target layer in a region located below an outer circumference of the shot region on an upper surface of the processing target object; forming the processing target layer on the processing target object on which the stopper film is formed; applying the transfer target material to the shot region on the upper surface of the processing target layer; transferring the pattern of the template to the transfer target material by bringing the template into contact with the transfer target material, and curing the transfer target material; releasing the template from the cured transfer target material; forming a reversal agent layer on the cured transfer target material so that a part of the cured transfer target material is exposed; and processing the processing target layer and the processing target object using the reversal agent layer as a mask.

An imprint method according to still another embodiment is an imprint method of applying a transfer target material to a shot region on a processing target layer formed on a processing target object and transferring a pattern of a template to the transfer target material. The imprint method includes: forming a first processing target layer on the processing target object; forming a stopper film that has higher processing resistance than the processing target layer in a region located below an outer circumference of the shot region on an upper surface of the first processing target layer; forming a second processing target layer on the first processing target layer on which the stopper film is formed and forming the processing target layer with the first and second processing target layers; applying the transfer target material to the shot region on the upper surface of the processing target layer; transferring the pattern of the template to the transfer target material by bringing the template into contact with the transfer target material, and curing the transfer target material; releasing the template from the cured transfer target material; forming a reversal agent layer on the cured transfer target material so that a part of the cured transfer target material is exposed; and processing the processing target layer and the processing target object using the reversal agent layer as a mask.

A method of manufacturing a semiconductor substrate according to at least one embodiment is a method of manufacturing a semiconductor substrate, the method including: applying a transfer target material to a shot region on a processing target layer formed on a substrate; transferring a pattern of a template to the transfer target material; and processing the substrate based on the transfer target material to which the pattern is transferred. In the method of manufacturing the semiconductor substrate, the substrate is used as a processing target object, and the substrate is processed using the foregoing imprint method.

A method of manufacturing a template according to at least one embodiment is a method of manufacturing a template, the method including: applying a transfer target material to a shot region on a processing target layer formed on a replica template; transferring a pattern of a master template to the transfer target material; and processing the replica template based on the transfer target material to which the pattern is transferred. In the method of manufacturing the template, the replica template is used as a processing target object and the replica template is processed by using the foregoing imprint method.

Hereinafter, embodiments will be described with reference to the drawings. To facilitate understanding of the description, the same elements in each drawing are denoted by the same reference numerals as much as possible and repeated description will be omitted.

### 1. First Embodiment

An imprint method and a method of manufacturing a semiconductor device according to a first embodiment will be described. A semiconductor device to which the manufacturing method according to the embodiment is applied is a nonvolatile memory device configured as a NAND flash memory.

### 1.1 Configuration of Semiconductor Device

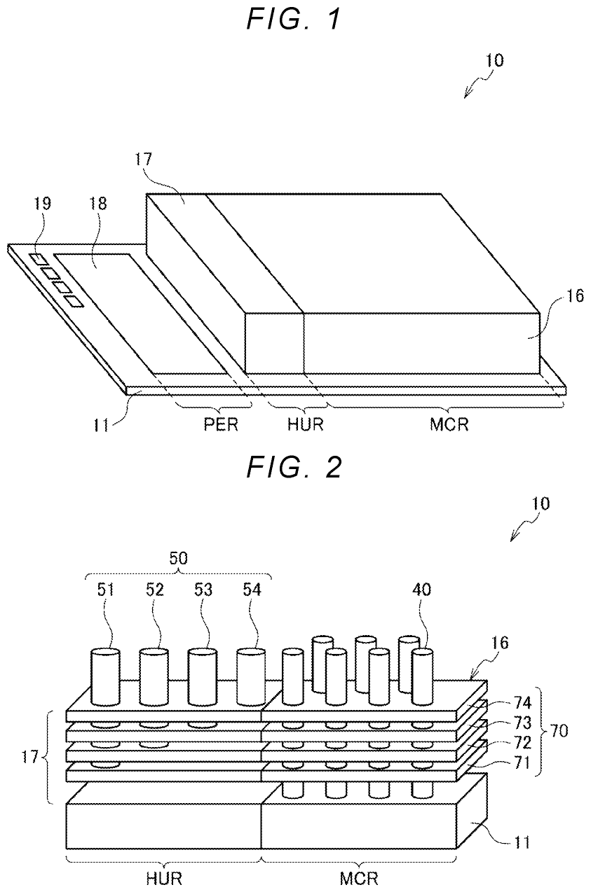

An overall configuration of the semiconductor device according to the embodiment will be described with reference to FIG. 1. FIG. 1 is a perspective view illustrating disposition of each element of a semiconductor device 10 according to the embodiment. As illustrated in FIG. 1, the semiconductor device 10 is formed on a semiconductor substrate 11. A memory cell region MCR and a contact region HUR are partitioned on the semiconductor substrate 11. A memory cell array 16 is formed in the memory cell region MCR. The memory cell array 16 includes a plurality of memory cells stacked three-dimensionally. Specifically, a source-side select gate transistor, many (for example, sixty four) memory cell transistors, and a drain-side select gate transistor are connected in series in a vertical direction on the surface of the semiconductor substrate 11 to form a memory string. Between both ends of the many memory cell transistors connected in series or between parts of the many memory cell transistors, dummy cell transistors may be included. The memory cell array 16 includes a stacked body in which a plurality of conductive layers serving as a source-side select gate line, a word line, and a drain-side select gate line connected to each transistor are each stacked with an insulating layer interposed therebetween. A stacked wiring structure 17 is formed by extending the plurality of conductive layers to the contact region HUR. On the memory cell array 16, bit lines (not illustrated) are connected to a peripheral circuit 18. On the stacked wiring structure 17, wirings (not illustrated) are connected to the peripheral circuit 18.

A peripheral circuit region PER is further partitioned on the semiconductor substrate 11. The peripheral circuit 18 is formed in the peripheral circuit region PER. The peripheral circuit 18 includes many CMOS transistors. The peripheral circuit 18 includes a column system circuit including a drive circuit that drives each word line connected to a memory cell, a decoder circuit that selects each word line, a sense amplifier that senses a voltage of a bit line in reading, and a bit line voltage control circuit that supplies a voltage to the bit line in writing. In FIG. 1, wirings of the peripheral circuit region PER are not illustrated. The semiconductor substrate 11 further includes a pad row 19 for supplying power to or exchanging signals with the chip outside.

### 1.2 Configurations of Memory Cell Region MCR and Contact Region HUR

FIG. 2 is a perspective view illustrating configurations of the memory cell region MCR and the contact region HUR of the semiconductor device 10 according to the embodiment. In FIG. 2, members having a conductive property are illustrated and members having an insulating property are not illustrated. In FIG. 2, portions not illustrated as members are insulated by an insulating material such as silicon dioxide.

As illustrated in FIG. 2, in the memory cell region MCR, the memory cell array 16 is formed on the semiconductor substrate 11. The semiconductor substrate 11 is formed by, for example, silicon monocrystalline. The memory cell array 16 includes conductive layers 71 to 74. The conductive layers 71 to 74 extend substantially in parallel to the surface of the semiconductor substrate 11. Hereinafter, the conductive layers 71 to 74 are also collectively referred to as “conductive layers 70”.

The memory cell array 16 includes the stacked body in which the plurality of conductive layer 70 are each stacked with the insulating layer interposed therebetween. FIG. 2 exemplifies a case in which the conductive layers are four layers, but the conductive layers may be further stacked as more layers such as 33 layers or 65 layers. These conductive layers function as the source-side select gate line, the word lines, or the drain-side select gate line connected to the transistors.

In the memory cell region MCR, memory pillars 40 penetrate through the plurality of conductive layers and the plurality of insulating layers. The memory pillar 40 is cylindrical and is configured such that a block insulating film including a silicon dioxide film, a charge storage film including a silicon nitride film, a tunnel insulating film including a silicon dioxide film, a semiconductor channel including an amorphous or a polycrystal silicon film, and a silicon dioxide film are stacked from the outer circumferential side to the central side. Parts of charge storage films located between the conductive layers 71 to 74 corresponding to the select gate line and the word lines, and the semiconductor channels function as parts of nonvolatile memory cells trapping carriers.

In the contact region HUR, the stacked wiring structure 17 is formed on the semiconductor substrate 11. In the contact region HUR, a plurality of insulating layers and a plurality of conductive layers extend from the memory cell region MCR. The stacked wiring structure 17 includes the conductive layers 71 to 74. The conductive layers 71 to 74 extend substantially in parallel to the surface of the semiconductor substrate 11. The stacked wiring structure 17 has a stacked body in which the plurality of conductive layers 70 are each stacked with an insulating layer interposed therebetween. FIG. 2 exemplifies a case in which the conductive layers are four layers, but the conductive layers may be further stacked as more layers such as 33 layers or 65 layers. The plurality of conductive layers 70 correspond to wirings drawn out from the source-side select gate line, the word lines, or the drain-side select gate line in the contact region HUR.

In the contact region HUR, the conductive layers 71 to 74 corresponding to the wirings drawn out from the select gate lines or the word lines are respectively connected to corresponding contact plugs 51 to 54. Hereinafter, the contact plugs 51 to 54 are also collectively referred to as “contact plugs 50”. FIG. 2 exemplifies a case in which the contact plugs 50 are four, but the same number of contact plugs 50 as the plurality of conductive layers may be disposed. Each contact plug 50 is drawn out on the stacked wiring structure 17 via a contact hole penetrating through the plurality of insulating layers and the plurality of conductive layers.

### 1.3 Configuration of Stacked Wiring Structure

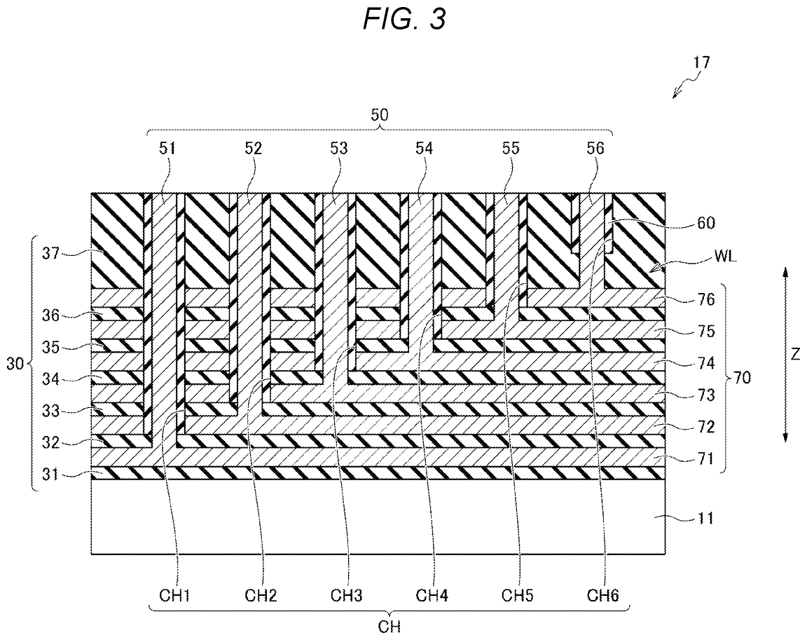

FIG. 3 is a sectional view illustrating a configuration of the stacked wiring structure 17. As illustrated in FIG. 3, the stacked wiring structure 17 has a structure in which the insulating layers 31 to 37 and the conductive layers 71 to 76 are alternately stacked on the semiconductor substrate 11. Hereinafter, the conductive layers 71 to 76 are also collectively referred to as the “conductive layers 70” and the insulating layers 31 to 37 are also collectively referred to as the “insulating layers 30”.

The plurality of conductive layers 70 and the plurality of insulating layers 30 are each alternately stacked one by one periodically in a direction (a stacking direction) vertical to a main surface of the semiconductor substrate 11. The insulating layer 31 is also formed between the semiconductor substrate 11 and the lowermost conductive layer 71. The insulating layer 37 is also on the uppermost conductive layer 76. The insulating layer 37 may be thicker than the insulating layers 31 to 36 in the stacking direction.

Each of the conductive layers 70 is a single layer. That is, when the cross-sectional shape of one conductive layer 70 is observed, a single material may continue in the film thickness direction of the conductive layer 70, that is, a direction indicated by an arrow Z in the drawing. There may be no interface in one conductive layer 70. Alternatively, the conductive layer 70 may be formed by two layers including a barrier metal layer and a metal layer. A material of the conductive layer 70 may be, for example, tungsten. The barrier metal layer may be, for example, titanium nitride (TiN) or tantalum nitride (TaN). The conductive layers 70 adjacent in the stacking direction may be insulated from each other or a material of the insulating layer 30 may be, for example, a silicon oxide such as silicon dioxide (SiO₂) or a tetra ethyl ortho silicate (TEOS). The insulating layers 30 are deposited using, for example, a chemical vapor deposition (CVD) device.

The conductive layers 71 to 76 are respectively connected to the corresponding contact plugs 51 to 56. Hereinafter, the contact plugs 51 to 56 are also collectively referred to as the “contact plugs 50”. The contact plugs 50 are drawn out on the stacked wiring structure 17 via contact holes CH1 to CH6 penetrating through the conductive layers 70 and the insulating layers 30 disposed on the corresponding conductive layers 70.

Specifically, in the stacked wiring structure 17, the contact hole CH1 penetrates through the insulating layers 32 to 37 and the conductive layers 72 to 76. The contact plug 51 is connected to the conductive layer 71 via the contact hole CH1. In the stacked wiring structure 17, the contact hole CH2 penetrates through the insulating layers 33 to 37 and the conductive layers 73 to 76. The contact plug 52 is connected to the conductive layer 72 via the contact hole CH2. Similarly, in the stacked wiring structure 17, the contact holes CH3 to CH6 are formed and the contact plugs 53 to 56 are respectively connected to the conductive layers 73 to 76 via the contact holes CH3 to CH6. Hereinafter, the contact holes CH1 to CH6 are also collectively referred to as the “contact holes CH”. Depths of each contact hole CH and each contact plug 50 from the upper surface of the stacked wiring structure 17 are different. All the contact plugs 50 are columnar, but the shape of the contact plugs 50 is not particularly limited. A material of the contact plug 50 may be, for example, a metal such as tungsten.

The contact plugs 50 are insulated from the upper conductive layers 70 through which the contact holes CH pass by the insulating films 60. The insulating films 60 are formed in a cylindrical shape at least a part of inner surfaces of the contact holes CH. Accordingly, at least a part of the outer surfaces of the contact plugs 50 are covered with the insulating films 60. A material of the insulating film 60 may be, for example, a silicon oxide such as silicon dioxide (SiO₂) or TEOS.

### 1.4 Method of Manufacturing Stacked Wiring Structure

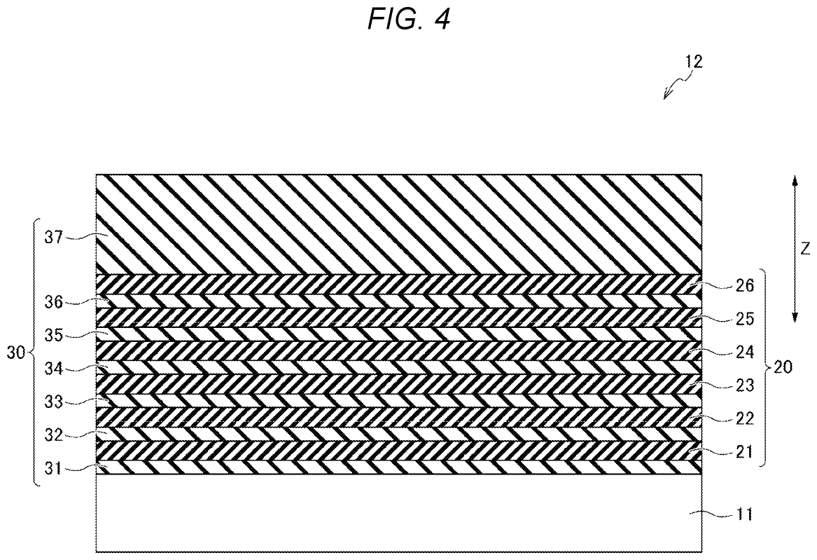

Next, a method of manufacturing the stacked wiring structure 17 according to the embodiment will be described. When the stacked wiring structure 17 illustrated in FIG. 3 is manufactured, a stacked body 12 illustrated in FIG. 4 is first formed. The stacked body 12 illustrated in FIG. 4 is formed by forming the insulating layers 31 to 37 and sacrifice layers 21 to 26 sequentially on the semiconductor substrate 11. Hereinafter, the sacrifice layers 21 to 26 are also collectively referred to as the “sacrifice layers 20”. The insulating layer 30 is, for example, a TEOS film and the sacrifice layer 20 is, for example, a SiN film. The sacrifice layer 20 and the insulating layer 30 are stacked using, for example, a CVD device. The insulating layers 30 and the sacrifice layers 20 alternately stacked are in contact with each other. In the embodiment, the TEOS film is exemplified as the material of the insulating layers 30, but the material of the insulating layers 30 is not limited thereto. For example, silicon dioxide (SiO₂) may be used. The silicon nitride film (SiN) is exemplified as the material of the sacrifice layer 20, but the material of the sacrifice layer 20 is not limited thereto. For example, silicon may be used.

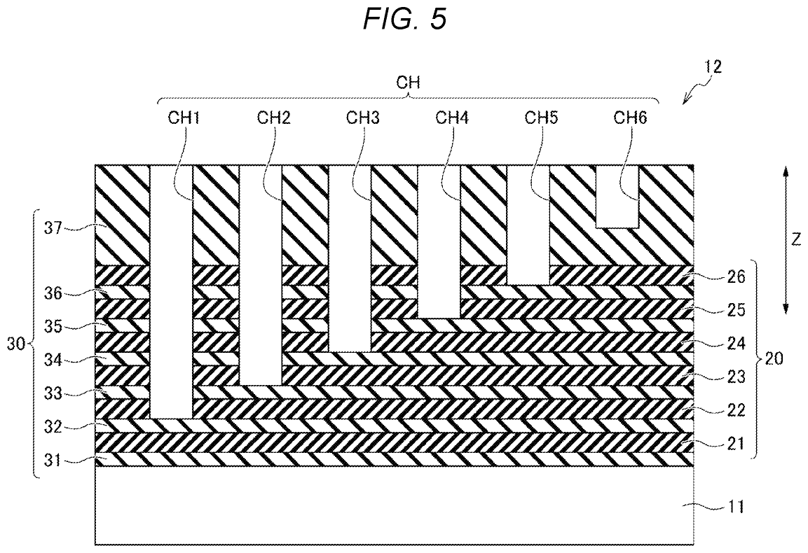

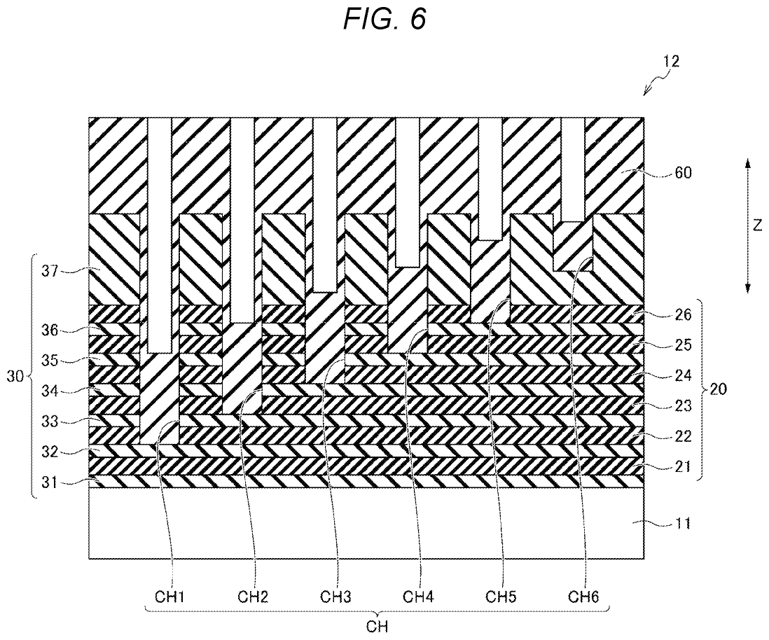

Subsequently, as illustrated in FIG. 5, the contact holes CH1 to CH6 are formed in the stacked body 12. This step is performed through, for example, a nanoimprint process. Hereinafter, the contact holes CH1 to CH6 are also collectively referred to as “contact holes CH”. Subsequently, as illustrated in FIG. 6, the insulating films 60 are formed on the upper surface of the stacked body 12, the inner side surfaces and the bottoms of the contact holes CH. The insulating films 60 may be, for example silicon oxides and are deposited using a CVD device.

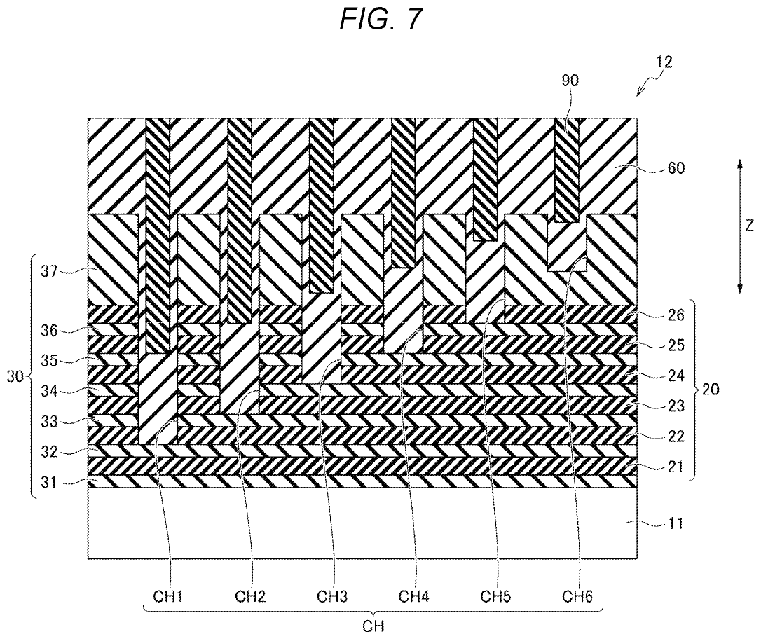

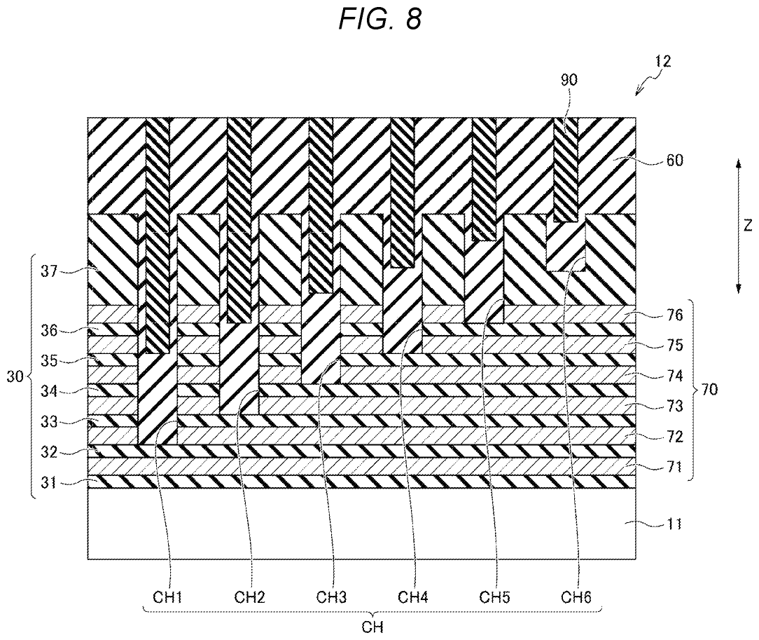

Subsequently, as illustrated in FIG. 7, insulators 90 are formed in the contact holes CH. The insulators 90 may be, for example, amorphous silicon and may be deposited using a CVD device. Subsequently, as illustrated in FIG. 8, the conductive layers 70 are formed in regions where the sacrifice layers 20 are disposed. For example, slits (not illustrated) are deepened in predetermined regions of the stacked body 12 and the sacrifice layers 20 provided in the stacked body 12 are collectively removed from the slits. As a result, cavities are formed in portions in which there are the sacrifice layers 20. The cavities are buried with a metal such as tungsten to form the conductive layers 70.

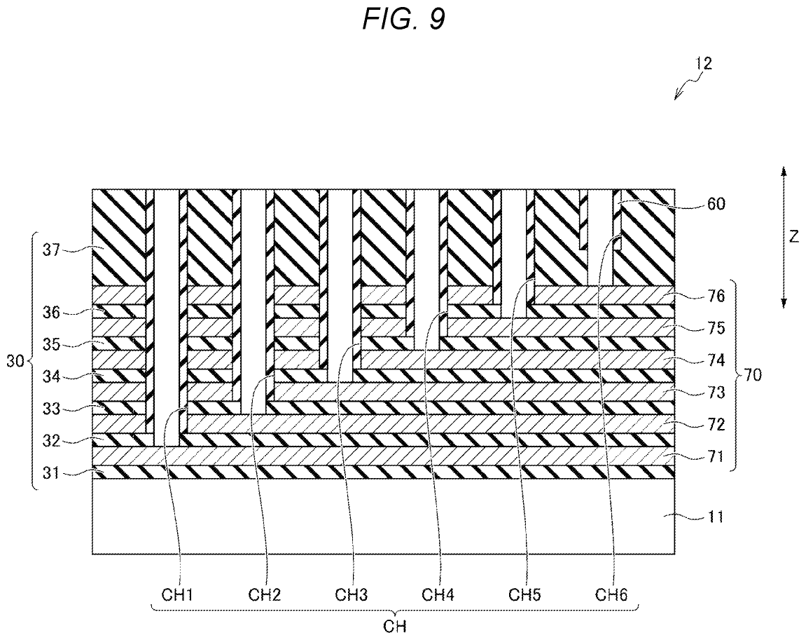

Subsequently, as illustrated in FIG. 9, the insulators 90 in the contact holes CH, the insulating films 60 on the upper surface of the stacked body 12 and in the bottoms of the contact holes CH, and the insulating layers 30 connected to the lower sides of the contact holes CH are removed, for example, by anisotropic etching such as RIE. The etching may be, for example, RIE using an HBr-based gas for the insulators 90, and a CF-based gas and an oxygen-based gas for the insulating films 60 and 30. By removing the insulating films 60 and the insulating layers 30 located below the insulators 90, the insulating films 60 remain on the inner side surfaces of the contact holes CH.

Subsequently, by burying the contact holes CH with, for example, a metal such as tungsten, the contact plugs 50 illustrated in FIG. 3 are formed. In the embodiment, the contact plugs 50, the conductive layers 70, and the like correspond to the wiring layers WL.

### 1.5 Configuration of Imprint Device

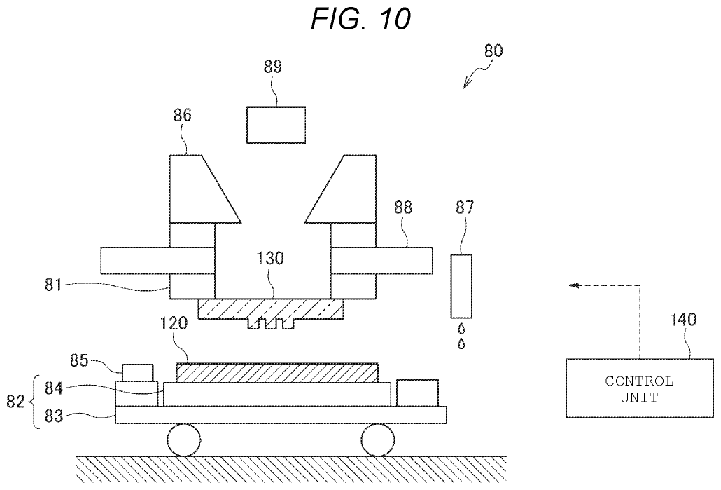

Next, the nanoimprint process used for the stacked body 12 illustrated in FIG. 4 when the contact holes CH illustrated in FIG. 5 are formed will be described. In the nanoimprint process, an imprint device 80 illustrated in FIG. 10 is used. Hereinafter, the stacked body 12 illustrated in FIG. 4 is referred to as a “substrate 120”. In the embodiment, the substrate 120 corresponds to a processing target object.

FIG. 10 is a diagram illustrating a configuration example of the imprint device 80 according to the first embodiment. As illustrated in FIG. 10, the imprint device 80 includes a template stage 81, a wafer stage 82, a reference mark 85, an alignment sensor 86, a liquid dropping device 87, a stage base 88, a light source 89, and a control unit 90. In the imprint device 80, a template 130 for transferring a minute pattern to organic chemicals on the substrate 120 to form a resist pattern is installed. The organic chemicals are, for example, photosetting chemicals cured when irradiated with light, and indicates a resist material before the curing. In the embodiment, the cured organic chemicals are referred to as a resist and may be distinguished from the organic chemicals before the curing.

The wafer stage 82 serving as a substrate stage includes a wafer chuck 84 and a body 83. The wafer chuck 84 fixes the substrate 120 serving as a semiconductor substrate to a predetermined position on the body 83. The reference mark 85 is provided on the wafer stage 82. The reference mark 85 is used for positioning when the substrate 120 is loaded onto the wafer stage 82.

The wafer stage 82 places the substrate 120 and is moved in a plane (in a horizontal plane) parallel to the placed substrate 120. The wafer stage 82 moves the substrate 120 to a position underneath the liquid dropping device 87 when the organic chemicals are dropped to the substrate 120. The wafer stage 82 moves the substrate 120 to a position underneath the template 130 when a transfer process to the substrate 120 is performed.

The stage base 88 supports the template 130 by the template stage 81 and moves the template 130 in the upper and lower directions (the vertical direction) to bring the minute pattern of the template 130 into contact with the organic chemicals on the substrate 120. The alignment sensor 86 is provided on the stage base 88. The alignment sensor 86 detects a position of the substrate 120 or detects a position of the template 130 based on positioning marks provided on the substrate 120 and the template 130.

The liquid dropping device 87 is a device that drops the organic chemicals to the substrate 120 by an ink jet scheme. An inkjet head provided in the liquid dropping device 87 includes a plurality of minute holes through which liquid droplets of the organic chemicals are ejected and drops the liquid droplets of the organic chemicals to the substrate 120. The light source 89 is a device that emits ultraviolet light and is provided above the stage base 88. The light source 89 in a state in which the template 130 is pressed against the organic chemicals irradiates the template 130 with the light from above.

The control unit 90 controls the template stage 81, the wafer stage 82, the reference mark 85, the alignment sensor 86, the liquid dropping device 87, the stage base 88, and the light source 89.

### 1.6 Method of Processing Substrate

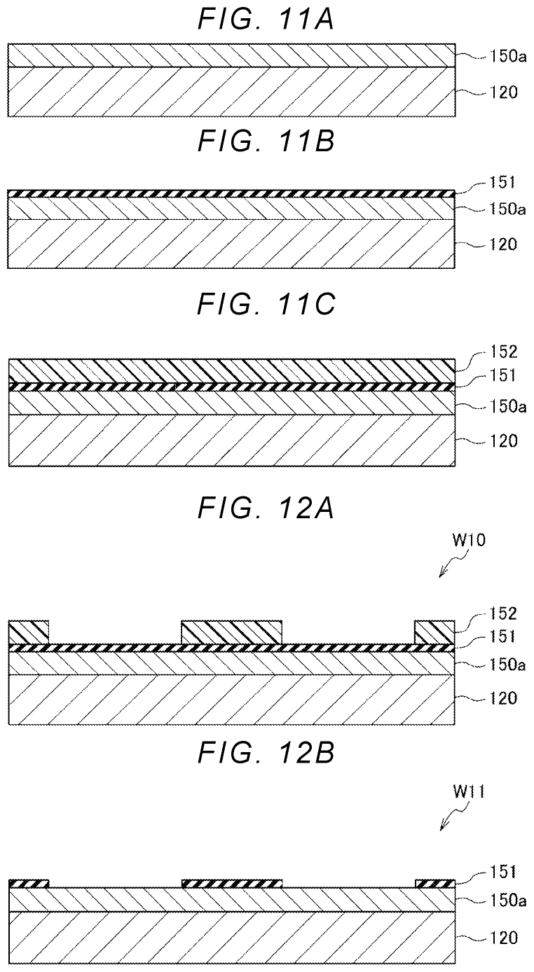

Next, a method of processing the substrate 120 using the imprint device 80 illustrated in FIG. 10 will be described with reference to FIGS. 11A to 15B.

As illustrated in FIG. 11A, when the substrate 120 is processed, a first processing target layer 150a is first formed on the substrate 120. The first processing target layer 150a is a carbon film such as a spin on carbon (SOC). Subsequently, as illustrated in FIG. 11B, a stopper film 151 is formed on the first processing target layer 150a by sputtering or immersion lithography. The stopper film 151 is formed of a material that has higher processing resistance than the first processing target layer 150a, for example, silicon nitride (SiN), titanium nitride (TiN), or titanium oxide (TiO). Immersion lithography is an exposure process that increases resolution by filling the space between the lenses of the exposure device and the wafer with liquid.

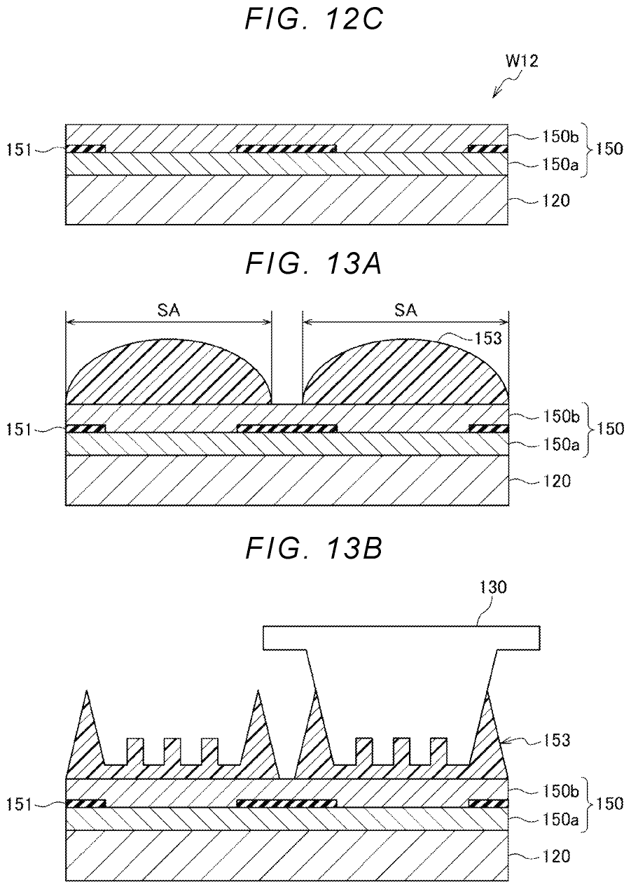

Subsequently, as illustrated in FIG. 11C, after a resist 152 is applied to the stopper film 151, a pattern of the stopper film 151 is transferred to the resist 152 to be developed. Accordingly, a work W10 illustrated in FIG. 12A is formed. As a method of transferring and developing the pattern to the resist 152, for example, photolithography is used. When the resist 152 is scraped with an electron beam or the like in a state illustrated in FIG. 11C, a pattern illustrated in FIG. 12A may be formed in the resist 152.

Subsequently, by performing etching process on the stopper film 151 using the resist 152 as a mask in the work W10 illustrated in FIG. 12A, the stopper film 151 that has a pattern illustrated in FIG. 12B is formed on the first processing target layer 150a. Accordingly, a work W1l illustrated in FIG. 12B is formed. When the resist 152 remains after the completion of the etching process, a process of removing the remaining resist 152 may be additionally performed.

Subsequently, as illustrated in FIG. 12C, a second processing target layer 150b is formed on the work W11 illustrated in FIG. 12B. Accordingly, a work W12 illustrated in FIG. 12C is formed. The second processing target layer 150b is formed by a film formed of the same material as the first processing target layer 150a, for example, a carbon film such as a spin on carbon (SOC). Hereinafter, the first processing target layer 150a and the second processing target layer 150b are also collectively referred to as the processing target layer 150.

Subsequently, an imprint process is performed on the work W12 illustrated in FIG. 12C using the imprint device 80 illustrated in FIG. 10. Specifically, after the work W12 is placed on the wafer stage 82 illustrated in FIG. 10, the wafer stage 82 is moved below the liquid dropping device 87. As illustrated in FIG. 13A, liquid droplets of organic chemicals 153 are dropped from the liquid dropping device 87 to the processing target layer 150 of the work W12. At this time, the liquid droplets of the organic chemicals 153 are dropped in predetermined shot regions SA set on the processing target layer 150. In the embodiment, the organic chemicals 153 correspond to a transfer target material.

Subsequently, when the wafer stage 82 illustrated in FIG. 10 is moved to below the template 130 and the template 130 is moved below while being positioned with the alignment sensor 86, the minute pattern of the template 130 is pressed against the organic chemicals 153, as illustrated in FIG. 13B. At this time, recess portions of the minute pattern of the template 130 are filled with the organic chemicals 153 by capillarity. The organic chemicals 153 disposed in a region overlapping with the outer edge of the template 130 are partially extruded to the outside of the template 130 to be leached into the side wall of the template 130 by capillarity.

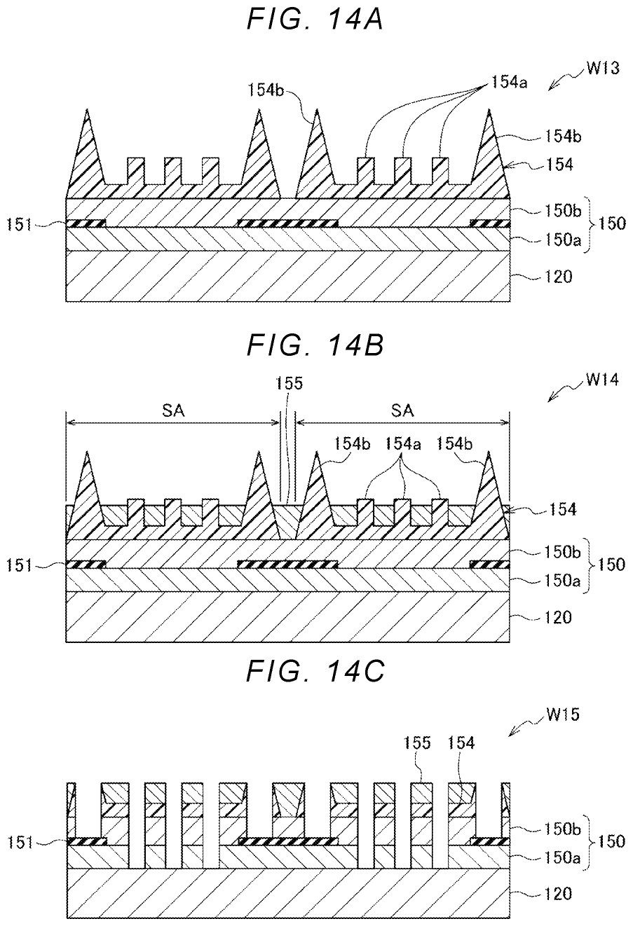

Subsequently, the organic chemicals 153 are irradiated with light from the light source 89 of the imprint device 80 illustrated in FIG. 10 with the template 130 remaining pressed against the organic chemicals 153, as illustrated in FIG. 13B. Accordingly, the organic chemicals 153 are cured to become a resist, so that the minute pattern of the template 130 is transferred to the resist. Thereafter, when the template 130 is released from the resist by moving the template 130 upward, a work W13 in which a resist 154 is provided on the processing target layer 150 as illustrated in FIG. 14 is formed. Hereinafter, in the resist 154, a portion to which the minute pattern of the template 130 is transferred is referred to as a “pattern forming portion 154a” and a portion leached into the side wall of the template 130 is referred to as a “leached portion 154b”. In the embodiment, the resist 154 corresponds to a cured transfer target material.

Subsequently, after a reversal agent layer is formed on a work W13 illustrated in FIG. 14A, a part of the reversal agent layer is removed by etching back the reversal agent layer by dry etching. Accordingly, a work W14 illustrated in FIG. 14B is formed. As illustrated in FIG. 14B, a reversal agent layer 155 is formed in the work W14 so that the upper surface of the pattern forming portions 154a of the resist 154 is exposed. In the work W14, the stopper film 151 is disposed in regions corresponding to the lower sides of the leached portions 154b of the resist 154.

Subsequently, an etching process is performed on the work W14 illustrated in FIG. 14B using the reversal agent layer 155 as a mask. Accordingly, the pattern forming portions 154a and the leached portions 154b exposed from the reversal agent layer 155 are etched and portions of the processing target layer 150 located on the lower side are also etched. Therefore, a work W15 illustrated in FIG. 14C is formed. At this time, in portions of the processing target layer 150 located below the leached portions 154b, portions of the second processing target layer 150b are etched, but further etching is blocked by the stopper film 151. Therefore, portions of the first processing target layer 150a located below the stopper film 151 are not etched. As a result, as illustrated in FIG. 14C, portions of the first processing target layer 150a and the second processing target layer 150b located below the pattern forming portion 154a of the resist 154 are etched, and thus the upper surface of the substrate 120 is exposed in these portions. Accordingly, the work W15 illustrated in FIG. 14C is formed.

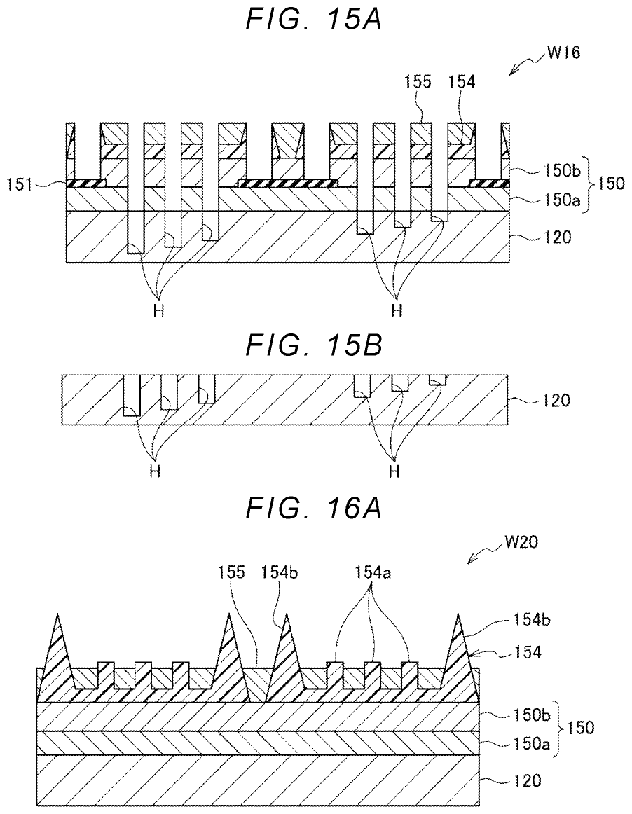

Subsequently, the work W15 is processed using, as masks, layers disposed above the substrate 120 in the work W15 illustrated in FIG. 14C. Accordingly, as illustrated in FIG. 15A, portions exposed on the substrate 120 are scraped to form a plurality of holes H in the substrate 120. As illustrated in FIG. 15A, the plurality of holes are formed so that depths of the holes H increase from the rightmost hole H to those on the left side in the figure. The holes H can be formed, for example, by applying a photoresist to the work W15 and then repeating an etching process using the photoresist as a mask and a slimming process of the photoresist. In the slimming process of the photoresist, portions corresponding to the upper surface of the holes H in the substrate 120 are sequentially exposed. Accordingly, while an etching process is performed on the portions exposed through the present slimming process and the portions exposed through the previous slimming process, no etching process is performed on the portions masked by the photoresist. Therefore, since an amount of scraping through the etching process can be sequentially changed with each of the holes H, the plurality of holes H with different depths can be formed in the substrate 120. The holes H illustrated in FIG. 15A are formed in, for example, the contact region HUR. Accordingly, a work W16 illustrated in FIG. 15A is formed. The holes H with substantially the same depths may be formed without forming the above-described slimming or the like. The holes H with substantially the same depths are formed in, for example, the memory cell region MCR.

Thereafter, the layers above the substrate 120, in other words, the processing target layer 150, the resist 154, the reversal agent layer 155 are collectively removed from the work W16 by wet etching or the like. At this time, since the stopper film 151 is provided in the processing target layer 150, the stopper film 151 is also removed along with the processing target layer 150.

In this way, by performing a process illustrated in FIG. 15B on the substrate 120, the stacked body 12 illustrated in FIG. 5 is manufactured. Thereafter, by sequentially performing the processes illustrated in FIGS. 6 to 9, the stacked wiring structure 17 illustrated in FIG. 3 is manufactured.

1.7 Operational Effects and Advantages of Imprint Method and Manufacturing method according to First Embodiment

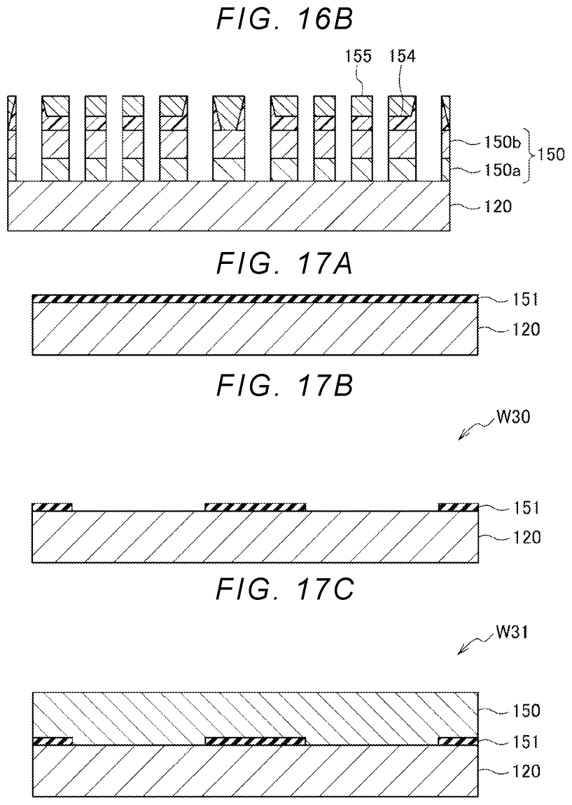

FIG. 16A illustrates a cross-sectional structure of a work W20 according to a reference example. The work W20 according to the reference example has a similar structure to the work W14 illustrated in FIG. 14B except that the stopper film 151 is not formed. When an etching process is performed on the work W20 according to the reference example illustrated in FIG. 16A using the reversal agent layer 155 as a mask and the leached portions 154b of the resist 154 is etched, as illustrated in FIG. 16B, there is concern of the portions of the processing target layer 150 (not illustrated) provided below the leached portions 154b being etched unintentionally. As a result, since the portions of the substrate 120 disposed below the leached portions 154b of the resist 154 are exposed, there is concern of the portions of the substrate 120 being processed unintentionally in subsequent processes. In the semiconductor device 10 according to the first embodiment, it is possible to prevent unintentional etching of the processing target layer 150.

Specifically, in the method of manufacturing the semiconductor device 10 according to the embodiment, as illustrated in FIG. 13A, the organic chemicals 153 are applied to the shot region SA on the processing target layer 150 formed on the substrate 120 to transfer the pattern of the template 130 to the organic chemicals 153. In the manufacturing method according to the embodiment, as illustrated in FIG. 12B, the first processing target layer 150a is formed on the substrate 120, and the stopper film 151 that has higher processing resistance than the processing target layer 150 is formed in a region located below the outer circumference of the shot region SA in the first processing target layer 150a. Subsequently, the second processing target layer 150b is formed on the first processing target layer 150a in which the stopper film 151 is formed, and the organic chemicals 153 is applied to the shot region SA on the upper surface of the processing target layer 150 including the first processing target layer 150a and the second processing target layer 150b. Further, after the template 130 is brought into contact with the organic chemicals 153, the organic chemicals 153 are irradiated with light and the organic chemicals 153 are cured to transfer the pattern of the template 130 to the organic chemicals 153. Subsequently, after the template 130 is released from the resist 154 which is the cured organic chemicals 153, the reversal agent layer 155 is formed on the resist 154 so that a part of the resist 154 is exposed. Then, the processing target layer 150 and the substrate 120 are processed using the reversal agent layer 155 as a mask.

In such a configuration, when the leached portions 154b of the resist 154 are etched in the process of processing the processing target layer 150 and the substrate 120 using the reversal agent layer 155 as a mask, as illustrated in FIG. 14C, the stopper film 151 disturbs the etching of the portions. As a result, since the portions of the substrate 120 located below the leached portions 154b of the resist 154 are not exposed, the unintentional processing of the substrate 120 can be prevented. Accordingly, it is possible to improve processing accuracy.

In the method of manufacturing the semiconductor device 10 according to the embodiment, the substrate 120 used for the imprint process includes the wiring layers WL such as the conductive layers 70 and the contact plugs 50. In such a configuration, when the manufacturing method according to the embodiment is applied to the method of manufacturing the substrate 120 including the wiring layers WL, the semiconductor device 10 illustrated in FIG. 2 can be easily manufactured.

### 2. Second Embodiment

Next, an imprint method and a method of manufacturing a semiconductor device according to a second embodiment will be described. Hereinafter, differences from the method of manufacturing the semiconductor device according to the first embodiment will be mainly described.

### 2.1 Method of Manufacturing Substrate

The manufacturing method according to the embodiment is different form the manufacturing method according to the first embodiment in that a stopper film 151 is formed not in a processing target layer 150 but on the upper surface of a substrate 120 when the imprint process is performed on the substrate 120. Specifically, in the embodiment, a manufacturing method illustrated in FIGS. 17A to 19B is used.

In the manufacturing method according to the embodiment, as illustrated in FIG. 17A, the stopper film 151 is first formed on the substrate 120. Thereafter, a work W30 illustrated in FIG. 17B is formed, for example, by performing photolithography and etching on the stopper film 151 as in the manufacturing method according to the first embodiment.

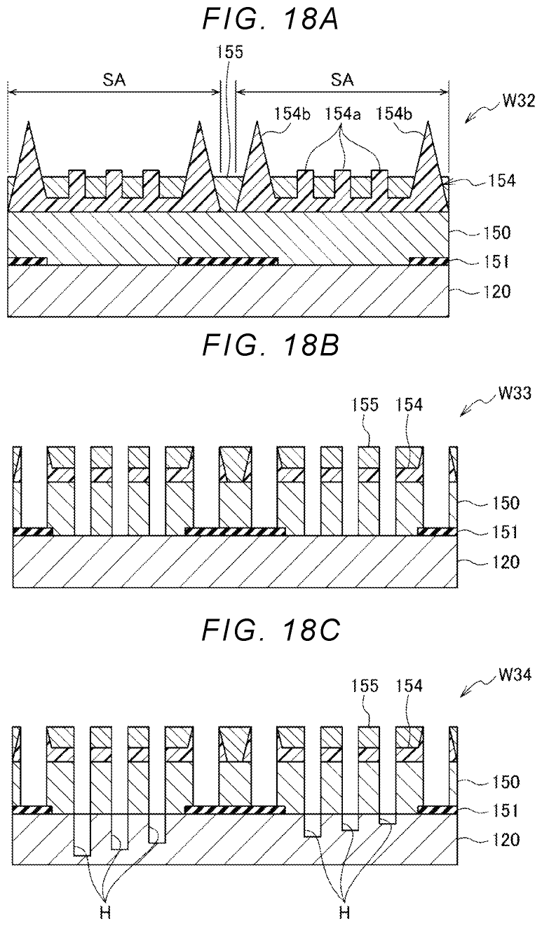

Subsequently, as illustrated in FIG. 17C, the processing target layer 150 is formed on the work W30 illustrated in FIG. 17B. Accordingly, a work W31 illustrated in FIG. 17C is formed. Subsequently, after a similar imprint process to that of the manufacturing method according to the first embodiment is performed on the work W31 illustrated in FIG. 17C using the imprint device 80, a work W32 illustrated in FIG. 18A is formed by forming the reversal agent layer 155.

Subsequently, an etching process is performed on the work W32 illustrated in FIG. 18A using the reversal agent layer 155 as a mask. Accordingly, the pattern forming portions 154a and the leached portions 154b exposed from the reversal agent layer 155 are etched and portions of the processing target layer 150 located below the pattern forming portions 154a and the leached portions 154b are also etched. Therefore, a work W33 illustrated in FIG. 18B is formed. At this time, the portions of the processing target layer 150 located below the leached portions 154b are etched, but further etching is blocked by the stopper film 151. As a result, as illustrated in FIG. 18B, in the upper surface of the substrate 120, portions located below the pattern forming portions 154a of the resist 154 are exposed, but portions located below the leached portions 154b are not exposed.

Subsequently, in the work W33 illustrated in FIG. 18B, the portions exposed on the substrate 120 are scraped to form the holes H, as illustrated in FIG. 18C, by processing the work W33 using the layers disposed above the substrate 120 as masks. Accordingly, a work W34 illustrated in FIG. 18C is formed.

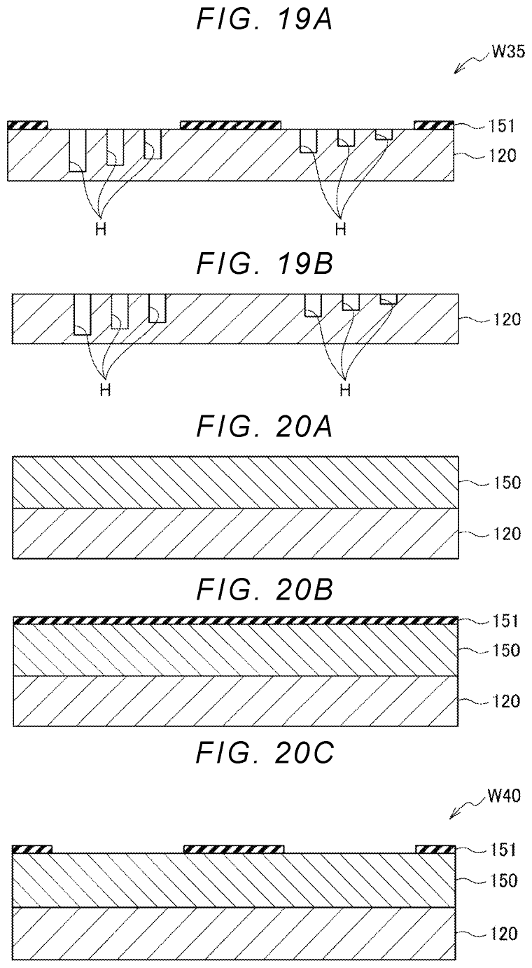

Subsequently, the layers above the substrate 120, specifically, the processing target layer 150, the resist 154, and the reversal agent layer 155 are collectively removed from the work W34 by performing wet etching or the like on the work W34 illustrated in FIG. 18C. Accordingly, a work W35 illustrated in FIG. 19A is formed. As illustrated in FIG. 19A, in the work W35, the stopper film 151 remains on the upper surface of the substrate 120. Therefore, in the manufacturing method according to the embodiment, the stopper film 151 is removed from the substrate 120, as illustrated in FIG. 19B, by further performing the etching process on the work W35 illustrated in FIG. 19A.

When it is difficult to remove only the stopper film 151 in the etching process, the substrate 120 may be etched along with the stopper film 151. Since the stopper film 151 is very thin, when a purpose for the etching is to remove the stopper film 151, the upper surface of the substrate 120 is slightly etched, and thus a possibility of product quality being problematic is low.

When the stopper film 151 formed on the upper surface of the substrate 120 is etched, there is a possibility of the upper surface of the substrate 120 after the etching being rough. Therefore, after the etching process is performed, a process of smoothing the upper surface of the substrate 120 may further be performed. Specifically, after a film of SiO₂ or the like is formed on the upper surface of the substrate 120, the upper surface of the substrate 120 is polished and smoothed by chemical mechanical polishing (CMP).

2.2 Operational Effects and Advantages of Imprint Method and Manufacturing method according to Second Embodiment

As described above, in the method of manufacturing the semiconductor device 10 according to the embodiment, as illustrated in FIG. 18A, the stopper film 151 is formed in the regions located below the outer circumferences of the shot regions SA on the upper surface of the substrate 120, and the processing target layer 150 is formed on the substrate 120 on which the stopper film 151 is formed.

In such a configuration, in comparison with the manufacturing method according to the first embodiment, the manufacturing processes can be simplified since it is not necessary to divide and form the processing target layer 150 into the first processing target layers 150a and the second processing target layers 150b. Accordingly, it is possible to manufacture the semiconductor device 10 more easily.

### 3. Third Embodiment

Next, an imprint method and a method of manufacturing a semiconductor device according to a third embodiment will be described. Hereinafter, differences from the method of manufacturing the semiconductor device according to the first embodiment will be mainly described.

### 3.1 Method of Manufacturing Substrate

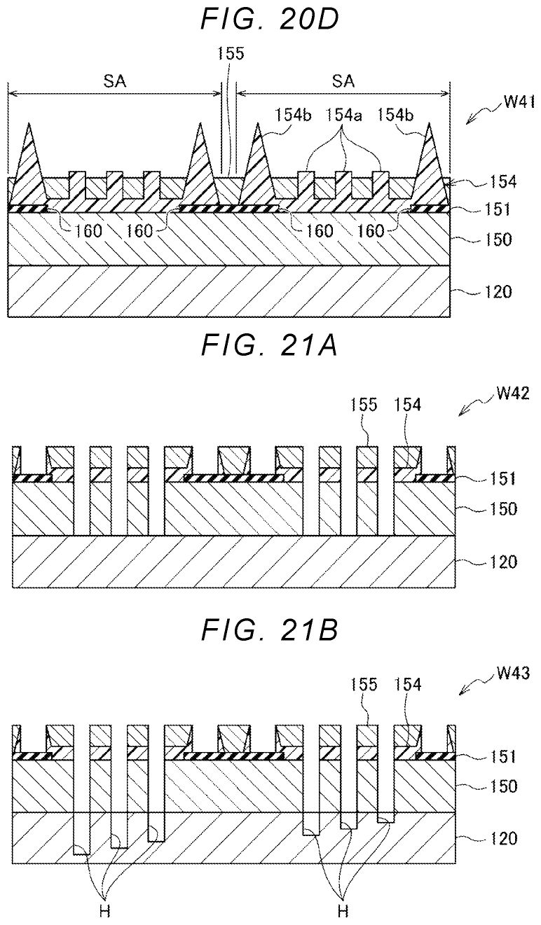

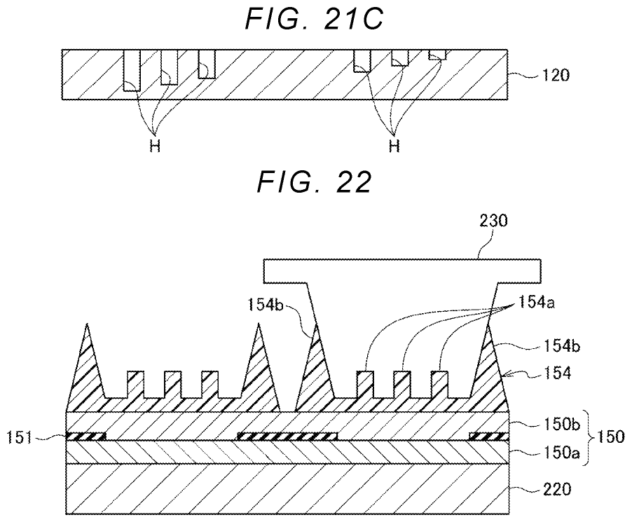

The manufacturing method according to the embodiment is different form the manufacturing method according to the first embodiment in that the stopper film 151 is formed not in the processing target layer 150 but on the upper surface of the processing target layer 150 when the imprint process is performed on the substrate 120. Specifically, in the embodiment, a manufacturing method illustrated in FIGS. 20A to 21 is used.

In the manufacturing method according to the embodiment, as illustrated in FIG. 20A, the processing target layer 150 is first formed on the substrate 120. Thereafter, as illustrated in FIG. 20B, the stopper film 151 is formed on the upper surface of the processing target layer 150. Thereafter, a work W40 illustrated in FIG. 20C is formed, for example, by performing photolithography and etching on the stopper film 151 as in the manufacturing method according to the first embodiment.

Subsequently, after a similar imprint process to that of the manufacturing method according to the first embodiment is performed on the work W40 illustrated in FIG. 20C using the imprint device 80, the reversal agent layer 155 forms a work W41 illustrated in FIG. 20D. Subsequently, an etching process is performed on the work W41 illustrated in FIG. 20D using the reversal agent layer 155 as a mask. Accordingly, the pattern forming portions 154a and the leached portions 154b exposed from the reversal agent layer 155 are etched and portions of the processing target layer 150 located below the pattern forming portions 154a and the leached portions 154b are also etched. Therefore, a work W42 illustrated in FIG. 21A is formed. At this time, the leached portions 154b are etched, but further etching is blocked by the stopper film 151. As a result, as illustrated in FIG. 21A, in the upper surface of the substrate 120, portions located below the pattern forming portions 154a of the resist 154 are exposed, but portions located below the leached portions 154b are not exposed.

Subsequently, in the work W42 illustrated in FIG. 21A, the portions exposed on the substrate 120 are scraped to form the holes H, as illustrated in FIG. 21B, by processing the work W42 using the layers disposed above the substrate 120 as masks. Accordingly, a work W43 illustrated in FIG. 21B is formed.

Subsequently, the layers above the substrate 120, specifically, the processing target layer 150, the resist 154, and the reversal agent layer 155 are collectively removed from the work W43 by performing wet etching or the like on the work W43 illustrated in FIG. 21B. At this time, since the stopper film 151 is formed on the upper surface of the processing target layer 150, the stopper film 151 is also removed along with the processing target layer 150. Accordingly, the substrate 120 illustrated in FIG. 21C is formed.

3.2 Operational Effects and Advantages of Imprint Method and Manufacturing method according to Third Embodiment

As described above, in the method of manufacturing the semiconductor device 10 according to the embodiment, as illustrated in FIG. 20D, the stopper film 151 is formed in the outer circumferences of the shot regions SA on the upper surface of the processing target layer 150.

In such a configuration, in comparison with the manufacturing method according to the first embodiment, the manufacturing processes can be simplified since it is not necessary to divide and form the processing target layer 150 into the first processing target layers 150a and the second processing target layers 150b. Accordingly, it is possible to manufacture the semiconductor device 10 more easily.

3.3 Supplements of Operational Effects and Advantages of Imprint Method and Manufacturing method according to First Embodiment

When the stopper film 151 is formed on the upper surface of the processing target layer 150 as in the third embodiment, as illustrated in FIG. 20D, steps 160 are formed between ends of the stopper film 151 and the upper surface of the processing target layer 150. When such steps 160 are formed and the template 130 illustrated in FIG. 10 is pressed against the organic chemicals, the template 130 comes into contact with the steps 160. Thus, there is concern of the template 130 being damaged.

From this viewpoint, when the manufacturing method according to the first embodiment is used, as illustrated in FIG. 13B, the stopper film 151 is not formed on the upper surface of the processing target layer 150. Therefore, when the template 130 is pressed against the organic chemicals 153, the template 130 does not collide with the steps. Therefore, it is possible to prevent the damage of the template 130 beforehand.

### 2. Other Embodiments

The present disclosure is not limited to the foregoing specific examples.

The imprint method and the manufacturing method according to each embodiment is applicable to not only processing of the substrate 120 but also processing of any object. For example, instead of the substrate 120 and the template 130 illustrated in FIG. 13B, when a replica template 220 and a master template 230 are used as illustrated in FIG. 22, the imprint method and the manufacturing method according to the first embodiment can be used to manufacture the replica template 220. Similarly, the imprint method and the manufacturing method according to the second embodiment and the imprint method and the manufacturing method according to the third embodiment can also be used to manufacture replica template 220.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

### 3. Supplements

Characteristics which can be ascertained from the foregoing embodiments and modifications are as follows.

A method of manufacturing a semiconductor device, in which a transfer target material is applied to a shot region on a processing target layer formed on a substrate, a pattern of a template is transferred to the transfer target material, and the substrate is processed based on the transfer target material to which the pattern is transferred, the method including:
forming the processing target layer on the substrate;
forming a stopper film that has higher processing resistance than the processing target layer in a region corresponding to an outer circumference of the shot region on an upper surface of the processing target layer;
applying the transfer target material to the shot region on the upper surface of the processing target layer on which the stopper film is formed;
transferring the pattern of the template to the transfer target material by bringing the template into contact with the transfer target material, and curing the transfer target material;
releasing the template from the cured transfer target material;
forming a reversal agent layer on the cured transfer target material so that a part of the cured transfer target material is exposed; and
processing the processing target layer and the substrate using the reversal agent layer as a mask.

A method of manufacturing a semiconductor device, in which a transfer target material is applied to a shot region on a processing target layer formed on a substrate, a pattern of a template is transferred to the transfer target material, and the substrate is processed based on the transfer target material to which the pattern is transferred, the method including:
forming a stopper film that has higher processing resistance than the processing target layer in a region located below an outer circumference of the shot region on an upper surface of the substrate;
forming the processing target layer on the substrate on which the stopper film is formed;
applying the transfer target material to the shot region on the upper surface of the processing target layer;
transferring the pattern of the template to the transfer target material by bringing the template into contact with the transfer target material, and curing the transfer target material;
releasing the template from the cured transfer target material;
forming a reversal agent layer on the cured transfer target material so that a part of the cured transfer target material is exposed; and
processing the processing target layer and the substrate using the reversal agent layer as a mask.

A method of manufacturing a semiconductor device, in which a transfer target material is applied to a shot region on a processing target layer formed on a substrate, a pattern of a template is transferred to the transfer target material, and the substrate is processed based on the transfer target material to which the pattern is transferred, the method including:
forming a first processing target layer on the substrate;
forming a stopper film that has higher processing resistance than the processing target layer in a region located below an outer circumference of the shot region on an upper surface of the first processing target layer;
forming a second processing target layer on the first processing target layer on which the stopper film is formed and forming the processing target layer with the first and second processing target layers;
applying the transfer target material to the shot region on the upper surface of the processing target layer;
transferring the pattern of the template to the transfer target material by bringing the template into contact with the transfer target material, and curing the transfer target material;
releasing the template from the cured transfer target material;
forming a reversal agent layer on the cured transfer target material so that a part of the cured transfer target material is exposed; and
processing the processing target layer and the substrate using the reversal agent layer as a mask.

A method of manufacturing a template, in which a transfer target material is applied to a shot region on a processing target layer formed on a replica template, a pattern of a master template is transferred to the transfer target material, and the replica template is processed based on the transfer target material to which the pattern is transferred, the method including:
forming the processing target layer on an upper surface of the replica template;
forming a stopper film that has higher processing resistance than the processing target layer in a region corresponding to an outer circumference of the shot region on an upper surface of the processing target layer;
applying the transfer target material to the shot region on the upper surface of the processing target layer on which the stopper film is formed;
transferring the pattern of the master template to the transfer target material by bringing the master template into contact with the transfer target material, and curing the transfer target material;
releasing the master template from the cured transfer target material;
forming a reversal agent layer on the cured transfer target material so that a part of the cured transfer target material is exposed; and
processing the processing target layer and the replica template using the reversal agent layer as a mask.

A method of manufacturing a template, in which a transfer target material is applied to a shot region on a processing target layer formed on a replica template, a pattern of a master template is transferred to the transfer target material, and the replica template is processed based on the transfer target material to which the pattern is transferred, the method including:
forming a stopper film that has higher processing resistance than the processing target layer in a region located below an outer circumference of the shot region on an upper surface of the replica template;
forming the processing target layer on the replica template on which the stopper film is formed;
applying the transfer target material to the shot region on the upper surface of the processing target layer;
transferring the pattern of the master template to the transfer target material by bringing the master template into contact with the transfer target material, and curing the transfer target material;
releasing the master template from the cured transfer target material;
forming a reversal agent layer on the cured transfer target material so that a part of the cured transfer target material is exposed; and
processing the processing target layer and the replica template using the reversal agent layer as a mask.

A method of manufacturing a template, in which a transfer target material is applied to a shot region on a processing target layer formed on a replica template, a pattern of a master template is transferred to the transfer target material, and the replica template is processed based on the transfer target material to which the pattern is transferred, the method including:
forming a first processing target layer on an upper surface of the replica template;
forming a stopper film that has higher processing resistance than the processing target layer in a region located below an outer circumference of the shot region on an upper surface of the first processing target layer;
forming a second processing target layer on the first processing target layer on which the stopper film is formed and forming the processing target layer with the first and second processing target layers;
applying the transfer target material to the shot region on the upper surface of the processing target layer;
transferring the pattern of the master template to the transfer target material by bringing the master template into contact with the transfer target material, and curing the transfer target material;
releasing the master template from the cured transfer target material;
forming a reversal agent layer on the cured transfer target material so that a part of the cured transfer target material is exposed; and
processing the processing target layer and the replica template using the reversal agent layer as a mask.

What is claimed is:

1. An imprint method of applying a transfer target material to a shot region on a processing target layer formed on a processing target object and transferring a pattern of a template to the transfer target material, the method comprising:
forming a first processing target layer on the processing target object;
forming, before forming the first processing target layer, a stopper film having a higher processing resistance than the processing target layer in a region located below an outer circumference of the shot region (i) on an upper surface of the processing target layer or (ii) on an upper surface of the processing target object;
applying the transfer target material to the shot region on the upper surface of the processing target layer on which the stopper film is formed;
transferring the pattern of the template to the transfer target material by bringing the template into contact with the transfer target material, and curing the transfer target material;
releasing the template from the cured transfer target material;
forming a reversal agent layer on the cured transfer target material in a manner that a part of the cured transfer target material is exposed; and
processing the processing target layer and the processing target object using the reversal agent layer as a mask.

2. The imprint method according to claim 1, wherein after forming the stopper film on an upper surface of the processing target layer, forming a second processing target layer on the first processing target layer on which the stopper film is formed.

3. The imprint method according to claim 1, wherein the stopper film is formed using the immersion lithography.

4. The imprint method according to claim 1, wherein the processing target object includes a wiring layer.

5. A method of manufacturing a semiconductor substrate, the method comprising:
applying a transfer target material to a shot region on a processing target layer formed on a substrate;
transferring a pattern of a template to the transfer target material; and
processing the substrate based on the transfer target material to which the pattern is transferred,
wherein the substrate is used as a processing target object and the substrate is processed by using an imprint method;
wherein the imprint method comprises:
forming a first processing target layer on the processing target object;
forming a stopper film having higher processing resistance than the processing target layer in a region located below an outer circumference of the shot region (i) on an upper surface of the processing target layer or (ii) on an upper surface of the processing target object before forming the first processing target layer;
applying the transfer target material to the shot region on the upper surface of the processing target layer on which the stopper film is formed;
transferring the pattern of the template to the transfer target material by bringing the template into contact with the transfer target material, and curing the transfer target material;
releasing the template from the cured transfer target material;
forming a reversal agent layer on the cured transfer target material in a manner that a part of the cured transfer target material is exposed; and
processing the processing target layer and the processing target object using the reversal agent layer as a mask.

6. The method of manufacturing a semiconductor substrate according to claim 5, wherein after forming a stopper film on an upper surface of the processing target layer, forming a second processing target layer on the first processing target layer on which the stopper film is formed.

7. The method of manufacturing a semiconductor substrate according to claim 5, further comprising forming the stopper film using immersion lithography.

8. The method of manufacturing a semiconductor substrate according to claim 5, wherein the processing target object includes a wiring layer.

9. A method of manufacturing a template, the method comprising:
applying a transfer target material to a shot region on a processing target layer formed on a replica template;
transferring a pattern of a template to the transfer target material; and
processing the replica template based on the transfer target material to which the pattern is transferred,
wherein the replica template is used as a processing target object and the replica template is processed by using an imprint method,
the imprint method comprising:
forming a first processing target layer on the processing target object;
forming, before forming the first processing target layer, a stopper film having higher processing resistance than the processing target layer in a region located below an outer circumference of the shot region (i) on an upper surface of the processing target layer or (ii) on an upper surface of the processing target object;
applying the transfer target material to the shot region on the upper surface of the processing target layer on which the stopper film is formed;
transferring the pattern of the template to the transfer target material by bringing the template into contact with the transfer target material, and curing the transfer target material;
releasing the template from the cured transfer target material;
forming a reversal agent layer on the cured transfer target material so that a part of the cured transfer target material is exposed; and
processing the processing target layer and the processing target object using the reversal agent layer as a mask.

10. The method of manufacturing a template according to claim 9, wherein after forming a stopper film on an upper surface of the processing target layer, forming a second processing target layer on the first processing target layer on which the stopper film is formed.

11. The method of manufacturing a template according to claim 9, wherein the stopper film is formed using immersion lithography.

12. The method of manufacturing a template according to claim 9, wherein the processing target object includes a wiring layer.

13. The method of manufacturing a semiconductor substrate according to claim 5, wherein the semiconductor substrate is formed of silicon.

14. The imprint method according to claim 1, wherein the stopper film is formed by at least one of SiN, TiN, or TiO.

15. The imprint method according to claim 1, wherein the forming the stopper film further comprising etching process.

16. The imprint method according to claim 1, wherein the processing target layer includes a carbon film.

17. The imprint method according to claim 1, wherein the transfer target material is formed of an organic material.

18. The imprint method according to claim 1, wherein the cured transfer target material includes a resist.
